(19) United States
(12) Patent Application Publication
(10) Pub. No.: US 2026/0245618 A1
(43) Pub. Date: Aug. 20, 2026

(54) DUAL RAIL MEMORY CIRCUITS AND METHODS FOR FORMING THE SAME

(71) Applicant: Taiwan Semiconductor Manufacturing Company, Ltd., Hsinchu (TW)

(72) Inventors: Yao-Jen Kuo, New Taipei City (TW); Li-Yue Huang, Hsinchu City (TW); Ming-Hung Chang, Hsinchu City (TW); Ching-Wei Wu, Hsinchu City (TW)

(73) Assignee: Taiwan Semiconductor Manufacturing Company, Ltd., Hsinchu (TW)

(21) Appl. No.: 19/265,279

(22) Filed: Jul. 10, 2025

Related U.S. Application Data
(60) Provisional application No. 63/760,207, filed on Feb. 19, 2025.

(51) Int. Cl. G11C 11/419; G01R 31/317; G11C 7/06; G11C 8/04; H03K 19/0185

(52) U.S. Cl. CPC G11C 11/419; G01R 31/31704; G11C 7/065; G11C 8/04; H03K 19/018578

(57) ABSTRACT

A circuit includes a memory array including memory cells; and input/output (I/O) circuits, each of the I/O circuits including a corresponding sense amplifier that is operatively coupled to a corresponding subset of the memory cells. Each of the I/O circuits includes a first input level shifter, a second input level shifter, and an output level shifter, each of the first input level shifter, the second input level shifter, and the output level shifter being coupled between a first voltage domain and a second voltage domain. The output level shifter has an input directly coupled to an output of a first multiplexer, the first multiplexer operating in the second voltage domain and configured to select one of a first signal present on a first input of the first multiplexer or a second signal present on a second input of the first multiplexer based on a first control signal.

### CROSS-REFERENCE TO RELATED APPLICATION

This application claims priority to and the benefit of U.S. Provisional Application No. 63/760,207, filed Feb. 19, 2025, which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density, sometimes referred to as complementary metal-oxide-semiconductor (CMOS) technology, has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram a memory circuit including a memory array, a control circuit, and an input/output circuit, in accordance with some embodiments.

FIG. 2 illustrates an example block diagram the memory circuit of FIG. 1 with various signal propagation paths annotated, in accordance with some embodiments.

FIG. 3 illustrates an example block diagram of the control circuit of the memory circuit of FIG. 1, in accordance with some embodiments.

FIG. 4 illustrates an example block diagram of the input/output circuit of the memory circuit of FIG. 1, in accordance with some embodiments.

FIG. 5 illustrates an example circuit diagram of the input/output circuit based on the block diagram of FIG. 4, in accordance with some embodiments.

FIG. 6 illustrates an example arrangement of the memory array with respect to the input/output circuit of the memory circuit of FIG. 1, in accordance with some embodiments.

FIG. 7 illustrates an example circuit diagram of a portion of the control circuit of the memory circuit of FIG. 1, in accordance with some embodiments.

FIG. 8 illustrates an example circuit diagram of an input/output redundancy circuit of the input/output circuit, in accordance with some embodiments.

FIG. 9 illustrates an example circuit diagram of an input level shifter of the memory circuit of FIG. 1, in accordance with some embodiments.

FIG. 10 illustrates an example circuit diagram of an output level shifter of the memory circuit of FIG. 1, in accordance with some embodiments.

FIG. 11 illustrates an example flow chart of a method for forming a memory circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A static random access memory (SRAM) device is a type of semiconductor memory device that stores data in the form of bits using bistable circuitry without the need for refreshing. An SRAM cell may sometimes be referred to as a bit cell of the SRAM device, given that the SRAM cell generally stores a bit of information or data. Each bit cell in a memory array typically includes connections to a power supply voltage and to a reference voltage, and is accessible through a number of access lines such as, for example, a pair of bit lines and a word line. The bit lines are configured for programming and/or reading the bit cell, with the word line controlling an access to the bit lines. One issue as the CMOS technology scales down is the choice of an appropriate power supply level. For example, increasing the power supply level may yield faster performance and improved reliability for memory cells and word line drivers that interface with memory cells. However, increasing the power supply level may increase leakage for other components.

One approach that has been used to address this issue while scaling down is referred to as a dual rail SRAM device, in which dual power rails are provided. For example, a first power supply voltage VDD is provided for a first group of components of the SRAM device (e.g., logic components), and a second power supply voltage VDDM, different from VDD, is provided for a second group of components of the SRAM device (e.g., memory cells, drivers). In one example, VDDM is higher than VDD. In another example, VDD is higher than VDDM. Level shifters are generally included in such a dual rail SRAM device to shift the voltage level from VDD to VDDM, or from VDDM to VDD. Stated another way, these level shifters are generally formed at the interface between the voltage domain of VDD and the voltage domain of VDDM. With this dual rail structure, faster performance and improved reliability for the SRAM device may be achieved without unduly increasing leakage for other components.

Typically, modern SRAM devices include various Design-for-Testing or Design for Testability (“DFT”) circuits, which refer to integrated circuit design techniques that add certain testability features to a hardware product design. The DFT features make it easier to develop and apply various manufacturing tests for the designed hardware. The purpose of manufacturing tests is to validate that the hardware products contain no manufacturing defects that could adversely affect the product's proper functioning.

To incorporate the DFT circuits to the forgoing dual rail structure, the existing SRAM device generally suffers from area penalty. For example, in the existing dual rail SRAM device, each input/output (I/O) circuit, corresponding to one column of bit cells of a memory array, includes two input level shifters and two output level shifters, each of which is formed at the interface of a first voltage domain (e.g., VDD domain) and a second voltage domain (e.g., VDDM domain). Given the most advanced design rule, one of the output level shifters needs to be physically arranged with respect to other level shifters from a layout perspective. As such, at least two isolation wells should be physically formed on the sides of the output level shifter, which disadvantageously increases an occupied area of the whole SRAM device. For another example, even with each I/O circuit corresponding to multiple columns of the bit cells, the layout for a controller of the SRAM device needs to be significantly redesigned, e.g., either a width or a height of the layout required to increase. Thus, the existing dual rail SRAM device, with the DFT features, has not been entirely satisfactory in certain aspects.

The present disclosure provides various embodiments of a memory device (e.g., a dual rail SRAM device) immune from the above-mentioned area penalty that the existing SRAM device is facing, while maintaining various DFT features. For example, the memory device, as disclosed herein, can shift its interface across different voltage domains (e.g., VDD and VDDM) toward its memory array, so as to reduce a total area occupied by the SRAM device. In one aspect, the disclosed memory device may shift some of its DFT circuits (e.g., a column repair circuit) from the VDDM domain to the VDD domain, when compared to the existing SRAM device. Accordingly, the number of input level shifter in a controller of the disclosed SRAM device can be significantly reduced, which can advantageously reduce the total area of the SRAM device. In another one aspect, the disclosed memory device, can have a plural number of I/O column circuits, each of which may correspond to one or more columns of bit cells. By directly coupling an output multiplexer in the VDDM domain to an output level shifter, each of the I/O column circuits, except for the edge I/O column circuits (which will be discussed below), may have two input level shifters and one output level shifter. As such, no additional isolation well needs to be disposed on both sides of the level shifters, and therefore, the total area of the SRAM device can be significantly reduced.

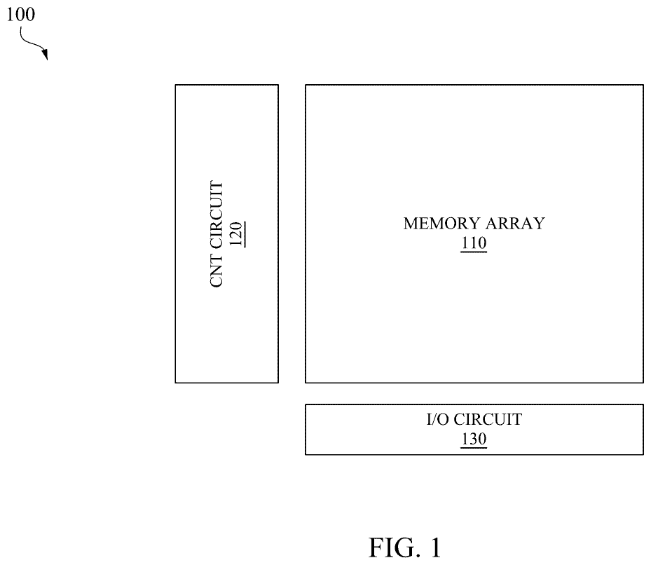

FIG. 1 illustrates a block diagram of an example memory device 100, in accordance with various embodiments. The memory device 100 is a storage device configured to be connected to an external host device (not illustrated). It should be appreciated that the memory device 100, as shown in FIG. 1, has been simplified, and thus, the memory device 100 can include any of various other components while remaining within the scope of the present disclosure. The memory device 100 can be configured with or integrated into an integrated circuit such as, for example, a system-on-a-chip (SoC) that may include one or more processing circuits, e.g., a Central Processing Unit (CPU), a Graphics Processing Unit (GPU), an Internet-of-Things (IoT) device, etc.

In general, the memory device 100 can store data in a non-volatile or volatile manner, which can include a memory array 110, a control (CNT) circuit 120, and an input/output (I/O) circuit 130 operatively coupled to each other, as shown in the illustrative example of FIG. 1. Although one memory array is shown, it should be understood that the memory device 100 can include any number of memory arrays and these memory arrays may operatively share the CNT circuit 120 and the I/O circuit 130, while remaining within the scope of the present disclosure. In various embodiments of the present disclosure, the memory device 100 is configured to operate with multiple voltage domains, e.g., VDD and VDDM, which is sometimes referred to as a dual rail memory device. A voltage level of VDD may be lower than or equal to a voltage level of VDDM. As some non-limiting examples, VDD=0.55V and VDDM=0.825V, VDD=0.66V and VDD=0.825V, VDD=0.77V and VDDM=0.825V, or VDD=0.825V and VDDM=0.825V.

The memory array 110 can include a plural number of memory cells, each of the memory cells configured to store one or more data bits. For example, the memory array 110 may include a static random-access memory (SRAM) array, a dynamic random-access memory (DRAM) array, a resistive random-access memory (RRAM) array, a magnetoresistive random access memory (MRAM) array, a phase change random access memory (PCRAM) array, etc. The memory array 110 can have its memory cells arranged in a column-row configuration, e.g., the memory cells disposed across a number of columns and a number of rows. As such, each of the memory cells of the memory array 110 can be accessed through a number of bit lines BLs disposed along the respective column(s) and a number of word lines WLs disposed along the respective row(s).

In various embodiments of the present disclosure, the memory device 100 is configured with various DFT features, such as the CNT circuit 120 and the I/O circuit 130 each including one or more DFT circuits. As a non-limiting example, the memory device 100 can be configured with at least three operation modes: a NORMAL mode, a SHIFT mode, and a CAPTURE mode. The SHIFT mode can include two sub-modes (states) respectively referred to as a SCAN SHIFT mode and a DEBUG SHIFT mode.

In the NORMAL mode, the memory device 100 does not perform any testing; instead, the memory device 100 performs, such as enabling reading and writing data bits from/to the memory array 110. In the SHIFT and CAPTURE modes, test-related features are invoked, and various testing functionality is performed on the components of the memory device 100 (e.g., the memory array 110) by applying certain input data to the components and comparing the output data with “designed” output data that the components are designed to produce. If the observed output matches the “designed” output then the components pass the test; if the observed output does not match the “designed” output, the components fail the test. In the SHIFT mode and CAPTURE mode, which can be considered as testing modes, tests are performed on different parts of the components. Each of the CNT circuit 120 and the I/O circuit 130 can include a testing circuit (sometimes referred to as a DFT circuit) to perform such testing features. Further, given that the memory device 100 is configured to operate with multiple voltage domains (e.g., VDD and VDDM), the CNT circuit 120 can have its testing circuit operating with VDD (and/or VDDM), and the I/O circuit 130 can have its testing circuit operating with both VDD and VDDM, according to some embodiments of the present disclosure. Details of the CNT circuit 120 and the I/O circuit 130 will be discussed in further detail below.

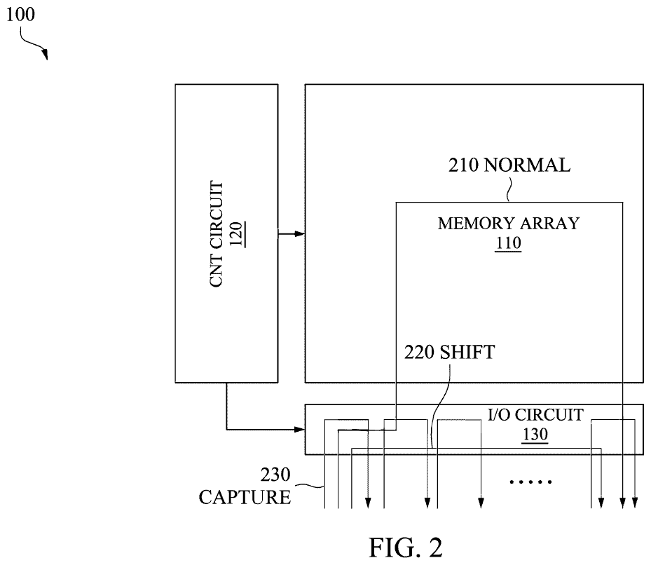

FIG. 2 is a schematic diagram of a portion of the memory device 100 illustrating various signal propagation paths corresponding to the memory device 100 being configured in the NORMAL mode, the SHIFT mode, and the CAPTURE mode, respectively, in accordance with various embodiments. It should be appreciated that the schematic diagram of FIG. 2 has been simplified for illustrative purposes, and does not intend to limit the scope of the present disclosure.

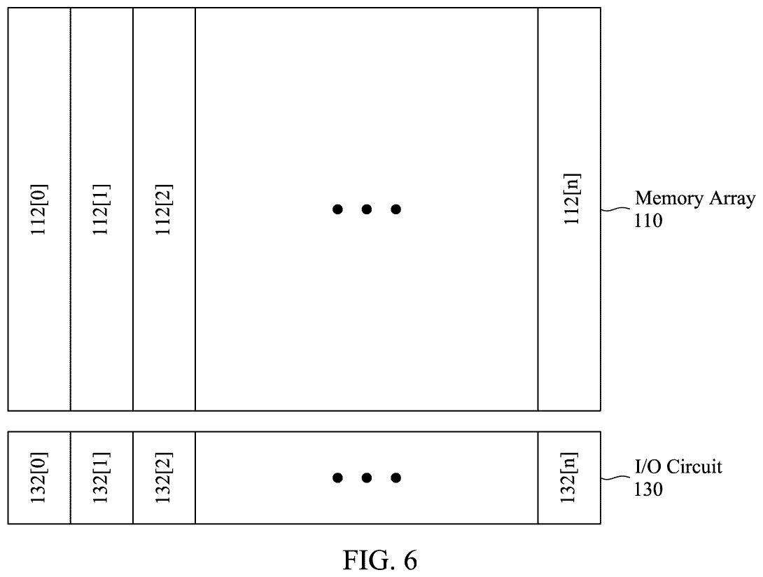

As shown, a NORMAL path 210 is associated with the NORMAL mode, a SHIFT path 220 is associated with the SHIFT mode, and a CAPTURE path 230 is associated with the CAPTURE mode. The NORMAL path 210 proceeds from an input portion of the I/O circuit 130, through a logic portion of the I/O circuit 130, the memory array 110, again the logic portion of the I/O circuit 130, and to an output portion of the I/O circuit 130. The SHIFT path 220 proceeds from the input portion of the I/O circuit 130 and to the output portion of the I/O circuit 130. The CAPTURE path 230 proceeds from the input portion of the I/O circuit 130, through the logic portion of the I/O circuit 130, and to the output portion of the I/O circuit 130. Further, the I/O circuit 130 can include a plural number of I/O column circuits, as will be discussed in further detail below (e.g., FIG. 6). In some embodiments, the SHIFT path 220 can proceed across (or connect) those different I/O column circuits, while the CAPTURE path 230 may be focused on a corresponding one of the I/O column circuits.

In general, adding testing capability to an integrated circuit (IC) hardware product includes developing and applying manufacturing tests on the IC hardware. The manufacturing test is to validate that the IC hardware contains no manufacturing defects that adversely affect the proper functioning of the IC hardware. The tests are generally driven by test programs that execute in Automatic Test Equipment (ATE) or inside the assembled system itself. In addition to detecting and indicating the presence of defects when a test fails, in some embodiments, tests are able to log diagnostic information about the nature of the encountered test failures. The diagnostic information can be used to locate the source of the failure. In the test, the response of vectors (patterns) from a “good” circuit (one that is known to be operating correctly) is compared against the response of vectors (using same patterns) from a device under test (DUT). If the response matches, the IC is in good condition. Otherwise, the IC contains defects and does not perform the purpose for which it is designed. For example, adding the testing capability to the I/O circuit 130 can be used for both testing purposes and normal operation within the memory device 100, depending on a mode of operation. By using circuit components such as multiplexers and latches which will be described below, the memory device 100 can provide multiple processing paths using shared hardware on an IC chip, reducing chip area and the number of components.

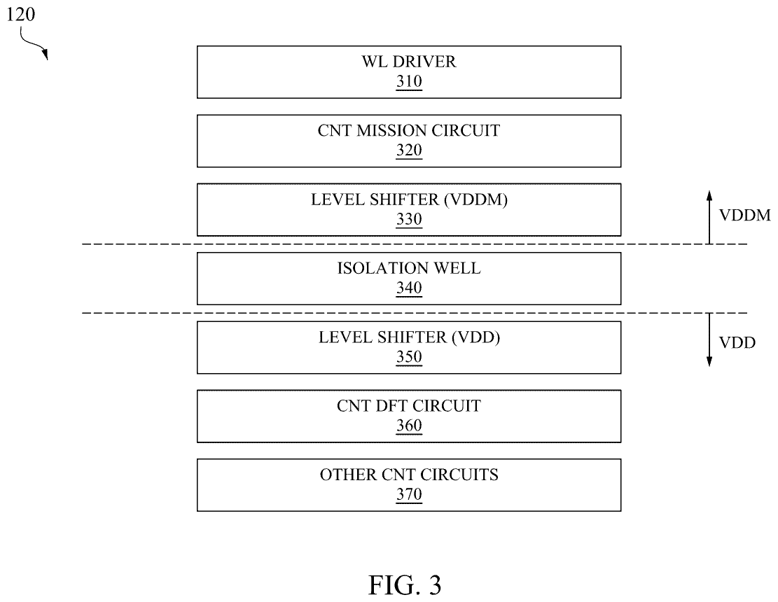

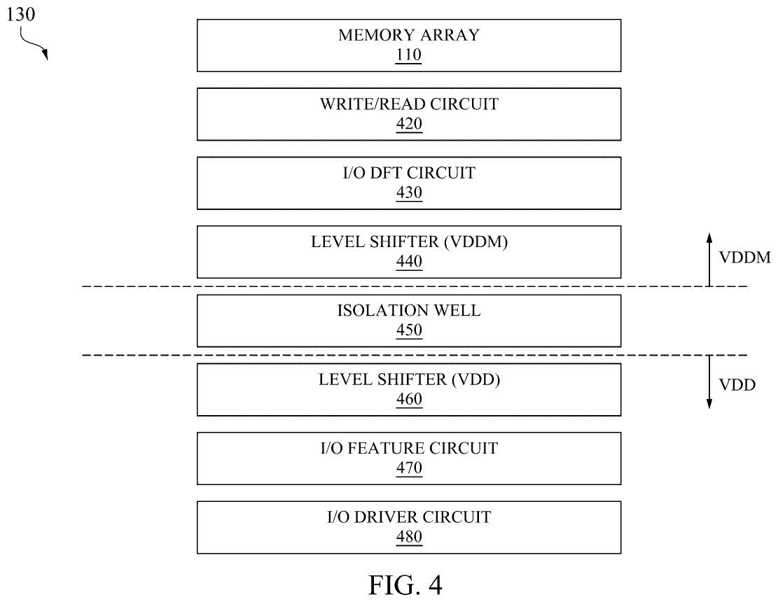

FIG. 3 and FIG. 4 illustrate block diagrams of non-limiting example implementations of the CNT circuit 120 and the I/O circuit 130, respectively, in accordance with various embodiments. As shown, each of the CNT circuit 120 and the I/O circuit 130 can include a respective number of functional blocks (each including a number of circuits), with a first subgroup of the functional blocks operating in the VDD domain and a second subgroup of the functional blocks operating in the VDDM domain. Further, these functional blocks can be physically arranged as shown. However, it should be appreciated that the functional blocks shown in each of FIGS. 3 and 4 have been simplified, and do not intend to limit the scope of the present disclosure.

In FIG. 3, the CNT circuit 120 includes the following functional blocks: a word line (WL) driver 310, a CNT mission circuit 320, a first portion of a group of level shifters configured in the VDDM domain (hereinafter “level shifter 330”), an isolation well 340, a second portion of the group of level shifters configured in the VDD domain (hereinafter “level shifter 350”), a CNT DFT circuit 360, and other CNT circuits 370. The CNT mission circuit 320 can further include an address decoder, a clock generator, a column selection circuit, a bit line (BL) pre-charge circuit, a sensing amplifier (SA) pulse circuit, etc. In some embodiments, other than the level shifter 330, the WL driver 310 and the CNT mission circuit 320 may be configured to operate in the VDDM domain; and, other than the level shifter 350, the CNT DFT circuit 360 and the other CNT circuits 370 may be configured to operate in the VDD domain. Further, the level shifter 330 and the level shifter 350 can be physically spaced from each other, with the isolation well 340 interposed therebetween. In some embodiments, the isolation well 340 can have a conductive type (e.g., n-type) opposite to the conductive type (e.g., p-type) of a substrate, on which the functional blocks 310-330 and 350-370 are formed.

In FIG. 4, with the memory array 110 shown as a reference, the I/O circuit 130 includes the following functional blocks: a write/read (W/R) circuit 420, I/O DFT circuit 430, a first portion of a group of level shifters configured in the VDDM domain (hereinafter “level shifter 440”), an isolation well 450, a second portion of the group of level shifters configured in the VDD domain (hereinafter “level shifter 460”), an I/O feature circuit 470, and an I/O driver circuit 480. In some embodiments, other than the level shifter 440, the memory array 110, the W/R circuit 420, and the I/O DFT circuit 430 may be configured to operate in the VDDM domain; and, other than the level shifter 460, the I/O feature circuit 470 and the I/O driver circuit 480 may be configured to operate in the VDD domain. Further, the level shifter 440 and the level shifter 460 can be physically spaced from each other, with the isolation well 450 interposed therebetween. In some embodiments, the isolation well 450 can have a conductive type (e.g., n-type) opposite to the conductive type (e.g., p-type) of a substrate, on which the functional blocks 420-440 and 460-480 are formed.

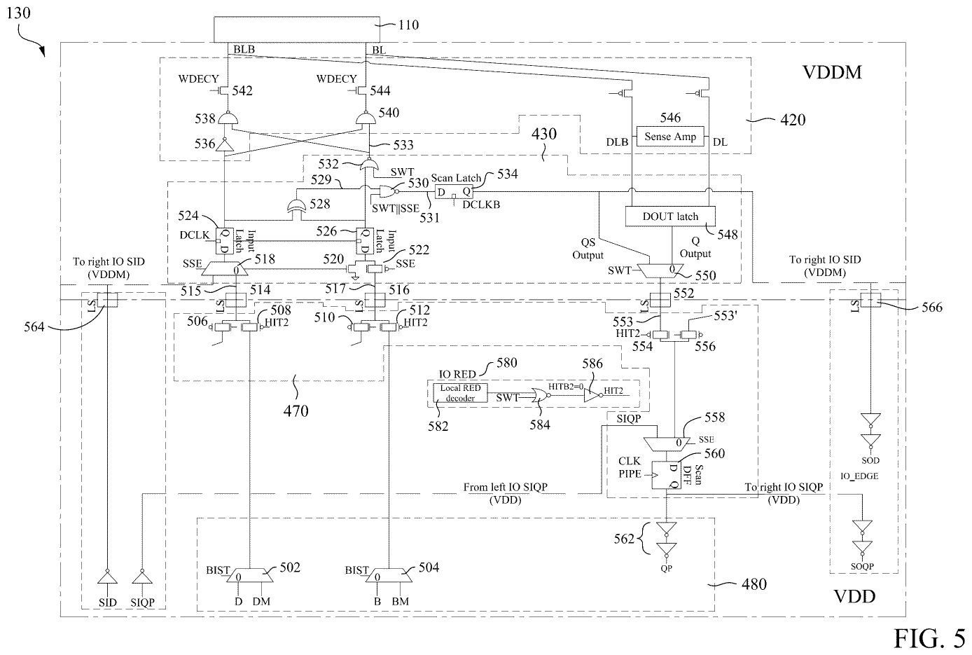

FIG. 5 illustrates an example circuit diagram of the I/O circuit 130 based on the functional blocks shown in FIG. 4, in accordance with various embodiments. For example, the circuit diagram of FIG. 5 includes the W/R circuit 420, the I/O DFT circuit 430, the level shifters 440 and 460, the I/O feature circuit 470, and the I/O driver circuit 480, as shown in FIG. 4. It should be understood that the circuit diagram of FIG. 5 has been simplified, and does not intend to limit the scope of the present disclosure.

As shown, the I/O circuit 130 includes a portion of the memory array 110 (e.g., a column of memory cells), multiplexers 502 and 504, transmission gates 506, 508, 510, and 512, input level shifters 514 and 516, multiplexer 518, transistor 520, transmission gate 522, latches 524 and 526, an exclusive OR (XOR) gate 528, a NAND gate 530, a NOR gate 532, a latch 534, an inverter 536, NAND gates 538 and 540, transistors 542 and 544, a sense amplifier 546, a latch 548, a multiplexer 550, an output level shifter 552, transmission gates 554 and 556, multiplexer 558, a latch 560, and inverters 562.

In some embodiments, the components 502 to 562 may sometimes be collectively referred to as one of plural I/O column circuit, and the plural I/O column circuits can operatively correspond to plural memory columns of the memory array 110, respectively. That is, the I/O circuit 130 includes the plural I/O column circuits. Each of these I/O column circuits may be coupled to one memory column of the memory array 110 (which includes a subset of the memory cells of the memory array 110), as depicted in FIG. 6. Further, each of the I/O column circuits (e.g., one of 132[0] to 132[n]) may include a respective portion of the W/R circuit 420 (e.g., the components 536 to 546), a respective portion of the I/O DFT circuit 430 (e.g., the components 518 to 550), a respective portion of the I/O feature circuit 470 (e.g., the components 506 to 560), and a respective portion of the I/O driver circuit 480 (e.g., the components 502-504 and 562), as depicted in FIG. 5.

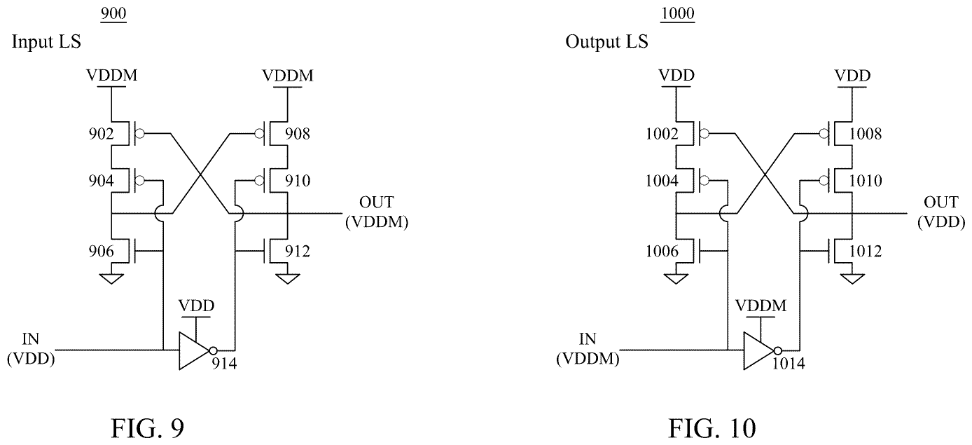

The W/R circuit 420 and the I/O DFT circuit 430 are configured to operate in the VDDM domain, and the I/O feature circuit 470 and the I/O driver circuit 480 are configured to operate in the VDD domain, with the input level shifters 514-516 and the output level shifter 552 operatively coupled between the VDDM domain and the VDD domain. The input level shifters 514-516 are each configured to convert a signal from the VDD domain to the VDDM domain, and the output level shifter 552 is configured to convert a signal from the VDDM domain to the VDD domain. As will be shown below in FIGS. 9-10, each of the level shifters 514, 516, and 552 can include a first portion of components (e.g., 440) and a second portion of components (e.g., 460) operative with the VDDM domain and with the VDD domain, respectively.

Corresponding to the memory columns of the memory array 110, the I/O column circuits of the I/O circuit 130 can form an I/O array. Referring to FIG. 6, the memory array 110 may include memory columns, 112[0], 112[1], 112[2] . . . 112[n], and respectively corresponding to the memory columns 112[0] to 112[n], the I/O circuit 130 may include I/O column circuits, 132[0], 132[1], 132[2] . . . 132[n]. In the example of FIG. 6, the memory columns and the I/O column circuit can present a one-to-one relationship. However, it should be understood that multiple memory columns can share a common I/O column circuit, in some other embodiments, while remaining within the scope of the present disclosure.

Still referring to FIG. 6, each of the I/O column circuits 132[0] to 132[n] can be operatively coupled to and physically located next to a respective one of the memory columns 112[0] to 112[n]. In some embodiments, such an I/O array (formed by the I/O column circuits 132[0] to 132[n]) may include a first edge I/O column circuit (e.g., 132[0]) and a second edge column circuit (e.g., 132[n]) that are coupled to and disposed along a first edge memory column (e.g., 112[0]) and a second edge memory column (e.g., 112[n]), respectively. Compared to those non-edge I/O column circuits, the first/second edge I/O column circuit can further include an input level shifter 564 and an output level shifter 566, as indicated in FIG. 5. During a SHIFT mode, the input level shifter 564 is configured to receive a shift input data signal (SID), shift it from the VDD domain to the VDDM domain, and provide the shifted SID signal to the first non-edge I/O column circuit; and the output level shifter is configured to receive a QS signal from the last non-edge I/O column circuit, and shift it from the VDDM domain to the VDD domain as a shift output data signal (SOD), which will be discussed as follows.

In some embodiments, the memory circuit 100 (or the I/O circuit 130) has several different operation modes such as, for example, a NORMAL mode (e.g., a read or write mode) and a DFT test mode (e.g., a SHIFT mode, and a CAPTURE mode), while the SHIFT mode includes two sub-modes sometimes referred to as a SCAN mode and a DEBUG mode, respectively.

In the NORMAL mode, the I/O circuit 130 does not perform any testing; instead, the I/O circuit 130 performs its regular functionality that it is designed to perform, such as enabling reading and writing of data from/to a memory, e.g., a static random access memory (SRAM). In some embodiments, a NORMAL path proceeds through an input portion of the I/O circuit 130 (e.g., 502-504), through the I/O feature circuit 470, the I/O DFT circuit 430, the W/R circuit 420, and the memory array 110, and then to an output portion of the I/O circuit 130 (e.g., 562).

In the SHIFT and CAPTURE modes, test-related features are invoked, and various testing functionality is performed on the memory circuit 100 by applying certain input data (for example, a data signal (SID) during the SHIFT mode and a data signal (D/DM) during the CAPTURE mode inputted) to the I/O circuit 130 and comparing an output data, e.g., an output signal (QP) in the CAPTURE mode or (SOD) in the SHIFT mode with “designed” output data that the I/O circuit 130 is designed to produce. If the observed output matches the “designed” output then the memory circuit 100 passes the test; if the observed output does not match the “designed” output, the memory circuit 100 fails the test. In the SHIFT mode and CAPTURE mode, which can be considered as test modes, tests are performed on different parts of the memory circuit 100. In some embodiments, a CAPTURE path and a SHIFT path both pass through the input portion of the I/O circuit 130 (e.g., 502-504), through the I/O feature circuit 470 and the I/O DFT circuit 430, and then to the output portion of the I/O circuit 130 (e.g., 562).

The multiplexer 502 is configured to output one of a D signal or a DM signal based on the logic state of a control signal (BIST), and the multiplexer 504 is configured to output one of a B signal or a BM signal based on the logic state of the BIST signal. For example, when the BIST signal is equal to logic 0, the multiplexer 502 outputs the D signal; and when the BIST signal is equal to logic 1, the multiplexer 502 outputs the DM signal. Similarly, when the BIST signal is equal to logic 0, the multiplexer 504 outputs the B signal; and when the BIST signal is equal to logic 1, the multiplexer 504 outputs the BM signal.

The transmission gate 508, coupled to the output of the multiplexer 502, is configured to selectively output the D signal or DM signal based on the logic state of a control signal (HIT2); and the transmission gate 512, coupled to the output of the multiplexer 504, is configured to selectively output the B signal or BM signal based on the logic state of the HIT2 signal. Further, coupled to the transmission gate 508, the transmission gate 506 is configured to selectively output a D signal or DM signal from a neighboring (e.g., left) I/O column circuit based on the logic state of the HIT2 signal; and coupled to the transmission gate 512, the transmission gate 510 is configured to selectively output a B signal or BM signal from the neighboring (e.g., left) I/O column circuit based on the logic state of the HIT2 signal.

Referring again to FIG. 6 as a non-limiting example, when the HIT2 signal is equal to logic 0, an output from the pair of transmission gates 506-508 is the D or DM signal inputted to the current I/O column circuit (e.g., 132[2]); and when the HIT2 signal is equal to logic 1, the output from the pair of transmission gates 506-508 is the D or DM signal inputted to the left I/O column circuit (e.g., 132[1]). Similarly, when the HIT2 signal is equal to logic 0, an output from the pair of transmission gates 510-512 is the B or BM signal inputted to the current I/O column circuit (e.g., 132[2]); and when the HIT2 signal is equal to logic 1, the output from the pair of transmission gates 510-512 is the B or BM signal inputted to the left I/O column circuit (e.g., 132[1]].

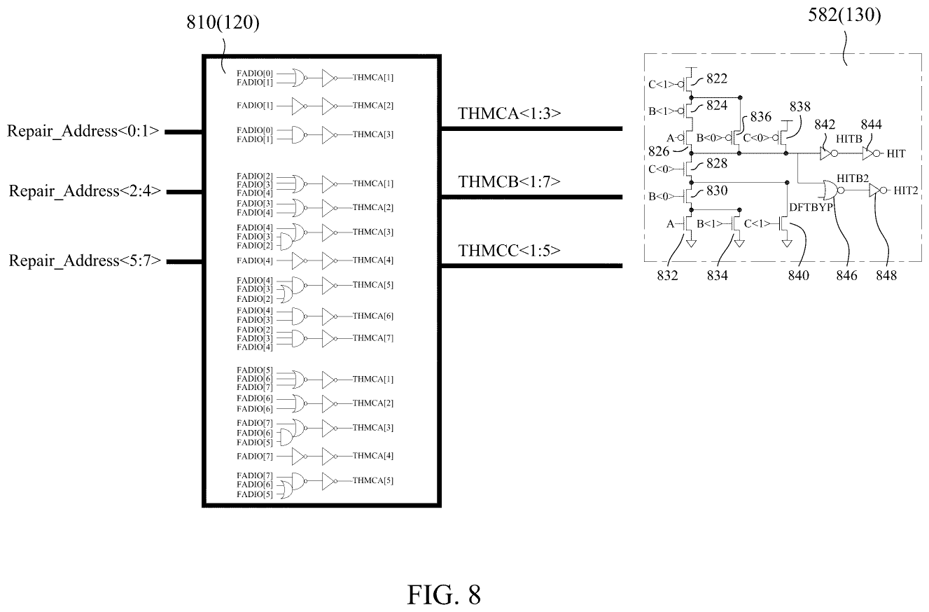

In some embodiments, the HIT2 signal, provided by an I/O redundancy circuit 580 (e.g., of the CNT circuit 120 or a part of the I/O feature circuit 470), may be indicative of whether to skip the current memory column coupled to the current I/O column circuit. For example, when a current memory column (of the array 110) is identified as abnormal or malfunctional (e.g., through the HIT2 signal being provided at logic 1), one or more inputs of the current I/O column circuit (e.g., the D/DM signal, the B/M signal) are shifted to a first neighboring (e.g., right) I/O column circuit, and one or more outputs of the current I/O column circuit (e.g., a Q signal) are shifted to a second neighboring (e.g., left) I/O column circuit. Referring again to FIG. 6, if the memory column 122[0] has been identified as abnormal or malfunctional, the input(s) originally to the I/O column circuit 132[0] are provided to the I/O column circuit 132[1] (and then to the corresponding memory column 122[1]) instead and the output(s) originally from the I/O column circuit 132[1] are provided to the I/O column circuit 132[0] instead, the input(s) originally to the I/O column circuit 132[1] are provided to the I/O column circuit 132[2] (and then to the corresponding memory column 122[2]) instead and the output(s) originally from the I/O column circuit 132[2] are provided to the I/O column circuit 132[1] instead, and so on. An example circuit diagram of the I/O redundancy circuit 580 configured to generate the HIT2 signal, will be discussed in FIG. 8.

Upon receiving the output (e.g., the D/DM signal of the current or left I/O column circuit) from the pair of transmission gates 506-508, the input level shifter 514 can convert the D/DM signal from the VDD domain to the VDDM domain as signal 515; and upon receiving the output (e.g., the D/DM signal of the current or left I/O column circuit) from the pair of transmission gates 506-508, the input level shifter 516 can convert the B/BM signal from the VDD domain to the VDDM domain as signal 517. The multiplexer 518 is configured to output one of the signal 515 or an SID signal from the left I/O column circuit based on the logic state of a control signal (SSE). In some embodiments, the logic state of the SSE signal is indicative of the operation mode configured for the memory circuit 100. For example, when the SSE signal is provided at logic 1, the memory circuit 100 is configured in the SHIFT mode; and when the SSE signal is provided at logic 0, the memory circuit 100 is configured in the CAPTURE mode or the NORMAL mode. The transistor 520 and the transmission gate 522 can also be controlled by the SSE signal, to selectively output the signal 517.

The latch 524 has its input connected to an output of the multiplexer 518 (to receive the signal 515 or the SID signal from the left I/O column circuit), and its output connected to a first input of the XOR gate 528. The latch 526 has its input connected to the transmission gate 522 and the transistor 520 (to receive the signal 517 or a ground signal), and its output connected to a second input of the XOR gate 528. The latches 524 and 526 are each implemented as a low-pass latch circuit which allow data to pass through when a data clock signal (DCLK) is low. In various embodiments, the latches 524 and 526 can be shared among the NORMAL, SHIFT and CAPTURE modes (or paths).

The XOR gate 528 can output signal 529 by XOR'ing the latched signals provided by the latches 524 and 526, respectively. The NAND gate 530 can output signal 531 by NAND'ing the signal 529 and a logic combination (e.g., an OR operation) of the SSE signal and a control signal (SWT). In some embodiments, a logic state of the SWT signal is indicative of the operation mode configured for the memory circuit 100. For example, when the SWT signal is provided at logic 1, the memory circuit 100 is configured in the CAPTURE mode; and when the SWT signal is provided at logic 0, the memory circuit 100 is configured in the SHIFT mode or the NORMAL mode. Further, the memory circuit 100 can be configured in the CAPTURE mode when the SWT and SSE signal are logic 1 and logic 0, respectively; in the SCAN SHIFT mode when the SWT and SSE signal are logic 1 and logic 1, respectively; in the DEBUG SHIFT mode when the SWT and SSE signal are logic 0 and logic 1, respectively; and in the NORMAL mode when the SWT and SSE signal are logic 0 and logic 0, respectively.

The NOR gate 532 can output signal 533 by NOR'ing the output of the latch 526 and the SWT signal. The signal 533 is applied on a bit line BL of the column of memory cells through the NAND gate 540, the other input of which is the output of the latch 524, and further through the transistor 544, which is gated by a write column selector signal WDECY. The output of the latch 524 is applied on a bit line bar BLB of the column of memory cells through the inverter 536, the NAND gate 538, the inputs of which are the inverted output of the latch 524 and the signal 533, respectively, and the transistor 542, which is also gated by the write column selector signal WDECY.

The signal 531 is provided to the latch 534. In some embodiments, when configured in the CAPTURE, SCAN SHIFT, or DEBUG SHIFT mode (e.g., SWT=1 and SSE=0, SWT=1 and SSE=1, or SWT=0 and SSE=1), the signal 531 can reflect the signal 529 XOR'ed by the XOR gate 528. On the other hand, when configured in the NORMAL mode (e.g., SWT=0 and SSE=0), the signal 531 may be constantly tied to logic 1. The latch 534 may be implemented as a high-pass latch circuit which allow data to pass through when a data clock signal (DCLKB) is high. The latch 534 can output the latched signal 531 as a signal (QS). The QS signal is provided to one of the inputs of the multiplexer 550, with the other input connected to the latch 548. The latch 548 may be implemented as a high-pass latch circuit allowing data to pass through when a clock signal is high. The latch 548 is coupled to the sense amplifier 546 through a first data line DL and a second data line DLB. The sense amplifier 546 is configured to sensing signals from the bit lines BL and BLB through the data lines DL and DLB that represent data bits stored in respective memory cells, and to amplify the small voltage swing to recognizable logic levels so the data can be interpreted properly by logic circuitry coupled to the memory cells. The latch 548 is configured to latch the read data and output to the other input of the multiplexer 550 as a signal (Q).

The multiplexer 550 is configured to output one of the Q signal or QS signal based on the logic state of the SWT signal. The Q signal may represent the read data bit when the memory circuit 100 is configured in the NORMAL mode, and the QS signal may represent the captured/shifted data bit when the memory circuit 100 is configured in the CAPTURE/SHIFT mode, in some embodiments. Specifically, in the SHIFT mode, the QS signal can be provided as an SID signal for the right I/O column circuit; and in the CAPTURE mode, the QS signal can be selected by the multiplexer 550. For example, when the SWT signal is provided at logic 0, the multiplexer 550 outputs the Q signal; and when the SWT signal is provided at logic 1, the multiplexer 550 outputs the QS signal. Upon receiving the output (e.g., the Q signal or the QS signal) from the multiplexer 550, the output level shifter 552 can convert the Q/QS signal from the VDDM domain to the VDD domain as signal 553.

The signal 553 is provided to the transmission gate 554, with the transmission gate receiving signal 553′. Both the transmission gates 554 and 556 are controlled by the HIT2 signal. When the HIT2 signal is equal to logic 0, an output from the pair of transmission gates 554-556 is the signal 553; and when the HIT2 signal is equal to logic 1, an output from the pair of transmission gates 554-556 is the signal 553′. In some embodiments, the signal 553 may represent the Q signal from the current memory column or the QS signal from the current I/O column circuit; and the signal 553′ may represent a Q signal from the right I/O column circuit. The signal 553 can be provided to the left I/O column circuit, when the current memory column is abnormal or malfunctional (e.g., as indicated by the HIT2 signal being provided at logic 1). The signal 553 or 553′ is then provided to the multiplexer 558, and the multiplexer 558 can select one of the signal 553 or 553′ based on the SSE signal. For example, when the SSE signal is provided at logic 0, the multiplexer 558 outputs the signal 553 or 553′; and when the SSE signal is provided at logic 1, the multiplexer 558 outputs another shift input signal (SIQP) from the left I/O column circuit. The multiplexer 558 can then output its selected signal as the QP signal through the latch 560 and inverters 562. The latch 560 can also output the SIQP signal to the right I/O column circuit.

In some embodiments, the SID signal received by the first edge I/O column circuit (e.g., 132[0] of FIG. 6) and the SOD signal outputted by the second edge I/O column circuit (e.g., 132[n] of FIG. 6), optionally with the D/DM signals, the B/BM signals, and the QS signals exchanged among the non-edge I/O column circuits (as discussed above), can form a first scan chain. In some embodiments, the SIQP signal received by the first edge I/O column circuit (e.g., 132[0] of FIG. 6) and a shift output signal (SOQP) outputted by the second edge I/O column circuit (e.g., 132[n] of FIG. 6), with the SIQP and SOQP signals exchanged among the non-edge I/O column circuits (as discussed above), can form a second scan chain.

During the write mode of the NORMAL mode (e.g., with the logic state of the B/BM signal provided at logic 0), the D/DM signal is received and selected by the multiplexer 502 of the I/O driver circuit 480 of the current I/O column circuit. If the corresponding memory column is not malfunctional (e.g., the HIT2 signal being provided at logic 0), the D/DM signal is transmitted to the multiplexer 518 of the I/O DFT circuit 430 through the transmission gate 508 of the I/O feature circuit 470 and the input level shifter 514. Further, during the write mode, the B/BM signal is received and selected by the multiplexer 504 of the I/O driver circuit 480 of the current I/O column circuit, and transmitted to the transmission gate 522 of the I/O DFT circuit 430 through the transmission gate 512 of the I/O feature circuit 470 and the input level shifter 516. The multiplexer 518, transistor 520, and transmission gate 522 are controlled by the SSE signal (e.g., provided at logic 0 in the NORMAL mode). Next, the D/DM signal (sometimes referred to as a write data signal) and the B/BM signal (sometimes referred to as a write enable signal) are transmitted to the latch 524 and 526 of the I/O DFT circuit 430, respectively, which are then applied on the BLB and BL, respectively, through the W/R circuit 420, so as to be programmed in the memory cell.

During the read mode of the NORMAL mode (e.g., with the logic state of the B/BM signal provided at logic 1), the components 536 to 544 can cause the bit line pair BL and BLB to be decoupled from the I/O DFT circuit 430. Thus, the data stored in the memory cell of the memory array 110 can be read out through the data line pair DL and DLB. The sense amplifier 546 of the W/R circuit 420 can provide the data signal read out from the memory cell (through the data line pair DL and DLB) to the latch circuit 548 of the I/O DFT circuit 430 for temporary storage. The data signal can pass through the multiplexer 550 of the I/O DFT circuit 430 and then passes through the I/O feature circuit 470 and I/O driver circuit 480, as the QP signal.

In the CAPTURE mode, the SWT signal is provided at logic 1, and the SSE signal may be provided at logic 0. The D/DM signal and the B/BM signal, respectively received by the multiplexers 502 and 504 of the I/O driver circuit 480 of the current I/O column circuit, are XOR'ed by the XOR gate 528 of the I/O DFT circuit 430 of the current I/O column circuit as the signal 529 which is passed to the NAND gate 530 of the I/O DFT circuit 430 of the current I/O column circuit. Given the logic combination of the SWT and SSE signals (e.g., logic 1), the NAND gate 530 can reflect the signal 529 and pass it to the latch 534 of the I/O DFT circuit 430 of the current I/O column circuit, which is provided as the QS signal. With the SWT signal provided at logic 1, the multiplexer 550 of the I/O DFT circuit 430 of the current I/O column circuit can select and output the QS signal to the I/O feature circuit 470 and the I/O driver circuit 480 of the current I/O column circuit through the output level shifter 552.

In the SHIFT mode, the SSE signal is provided at logic 1, and the SWT signal may be provided at logic 0 or 1. The D/DM signal and the B/BM signal, respectively received by the multiplexers 502 and 504 of the I/O driver circuit 480 of the left I/O column circuit (or the first edge I/O column circuit), are XOR'ed by the XOR gate 528 of the I/O DFT circuit 430 of the current I/O column circuit as the signal 529. In other words, in the SHIFT mode, the XOR gate 528 is not configured to receive a D/DM signal or a B/BM signal of the current I/O column circuit. The signal 529 is passed to the NAND gate 530 of the I/O DFT circuit 430 of the current I/O column circuit. Given the logic combination of the SWT and SSE signals (e.g., logic 1), the NAND gate 530 can reflect the signal 529 and pass it to the latch 534 of the I/O DFT circuit 430 of the current I/O column circuit, which is provided as the QS signal. The QS signal is then provided to the multiplexer 518 of the I/O DFT circuit 430 of the right I/O column circuit and passed to the rest of components of the I/O DFT circuit 430 of the right I/O column circuit, which can be passed down to the next right I/O column circuit.

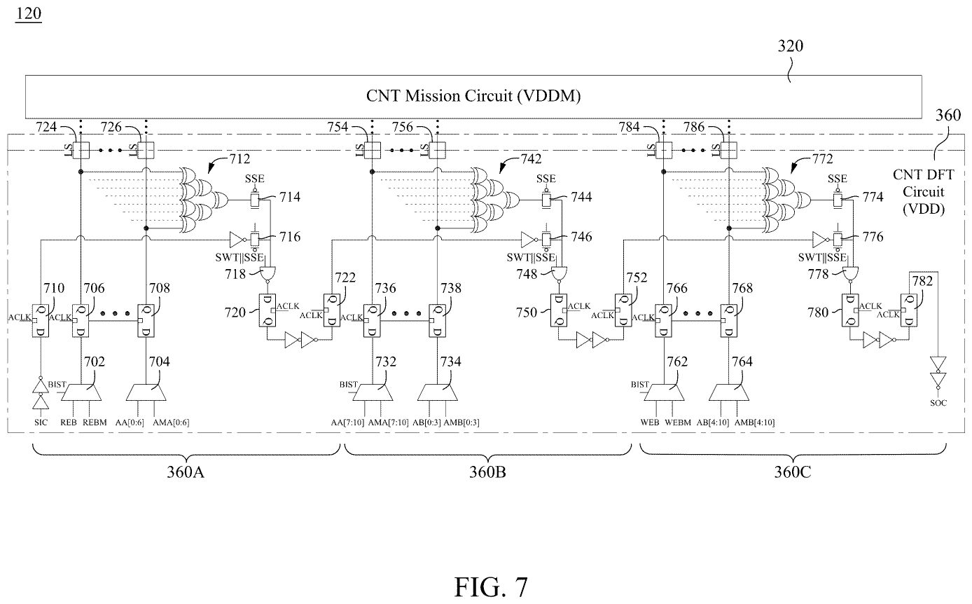

FIG. 7 illustrates an example circuit diagram of a portion of the CNT circuit 120 based on the functional blocks shown in FIG. 3, in accordance with various embodiments. For example, the circuit diagram of FIG. 7 includes the CNT DFT circuit 360 operating in the VDD domain, as shown in FIG. 3. It should be understood that the circuit diagram of FIG. 7 has been simplified, and does not intend to limit the scope of the present disclosure.

In some embodiments, the CNT DFT circuit 360 is configured to test the CNT circuit 120 such as, for example, the CNT mission circuit 320, the WL driver 310, etc. The CNT DFT circuit 360 (of the CNT circuit 120) can concurrently perform the testing (e.g., the above-mentioned DFT features) with the I/O DFT circuit 430 (of the I/O circuit 130). For example, the CNT DFT circuit 360 can be configured in the various operation modes, the NORMAL mode, the SHIFT mode, and the CAPTURE mode, etc., based on the control signals, SSE and SWT. In general, the CNT DFT circuit 360 can receive various control/address signals such as, read enable signals (e.g., REB/REBM), write enable signals (e.g., WEB/WEBM), address signals for read operation (e.g., AB[0:10]), address signals for write operation (e.g., AA[0:10]), for performing the DFT features.

As shown, the CNT DFT circuit 360 includes three major portions, 360A, 360B, and 360C, to respectively receive the foregoing control/address signals, but it should be understood that the CNT DFT circuit 360 can be divided into any number of functional portions while remaining within the scope of the present disclosure. In some embodiments, the portion 360A can receive a shift input control signal (SIC), the REB/REBM signals, and a portion of the AA signals; the portion 360B can receive another portion of the AA signals and a portion of the AB signals; and the portion 360C can receive the WEB/WEBM signals and another portion of the AB signals.

Specifically, the portion 360A can include a number (e.g., 8) of multiplexers 702 and 704, a number (e.g., 8) of latches 706 to 708, an input latch 710, a first group of XOR gates 712, transmission gates 714 and 716, a NAND gate 718, latches 720 and 722, and a number (e.g., 8) of input level shifters 724 to 726; the portion 360B can include a number (e.g., 8) of multiplexers 732 and 734, a number (e.g., 8) of latches 736 to 738, a second group of XOR gates 742, transmission gates 744 and 746, a NAND gate 748, latches 750 and 752, and a number (e.g., 8) of input level shifters 754 to 756; and the portion 360C can include a number (e.g., 8) of multiplexers 762 and 764, a number (e.g., 8) of latches 766 to 768, a third group of XOR gates 772, transmission gates 774 and 776, a NAND gate 778, latches 780 and 782, and a number (e.g., 8) of input level shifters 784 to 786. As mentioned above, the CNT DFT circuit 360 can be configured in the NORMAL mode, the CAPTURE mode, and the SHIFT mode, concurrently with the I/O circuit 130, for testing the components of the CNT circuit 120, which will be briefly described as follows.

In the NORMAL mode (e.g., SWT=0 and SSE=0), the CNT DFT circuit 360 can receive the REB/REBM signals, the AA signals, the AB signals, and the WEB/WEBM signals. The latches 706 to 708 (of the first portion) can latch the REB/REBM signals and the first portion of the AA signals, and pass those signals to the level shifters 724 to 726 to be shifted from the VDD domain to the VDDM domain. The latches 736 to 738 (of the second portion) can latch the second portion of the AA signals and the first portion of the AB signals, and pass those signals to the level shifters 754 to 756 to be shifted from the VDD domain to the VDDM domain. The latches 766 to 768 (of the third portion) can latch the WEB/WEBM signals and the second portion of the AB signals, and pass those signals to the level shifters 784 to 786 to be shifted from the VDD domain to the VDDM domain. Those shifted signals can be sent to the CNT mission circuit 320 (e.g., as read/write clock generation signals) and the WL driver 310 (e.g., as decoded address signals), to read/write the memory circuit 100.

In the CAPTURE mode (e.g., SWT=1 and SSE=0), the CNT DFT circuit 360 can receive the REB/REBM signals, the AA signals, the AB signals, and the WEB/WEBM signals. The latches 706 to 708 (of the first portion) can latch the REB/REBM signals and the first portion of the AA signals, which can be passed through the first group of XOR gates 712, the transmission gate 714, and the NAND gate 718, and be latched in the latches 720-722. The latches 736 to 738 (of the second portion) can latch the second portion of the AA signals and the first portion of the AB signals, which can be passed through the second group of XOR gates 742, the transmission gate 744, and the NAND gate 748, and be latched in the latches 750-752. The latches 766 to 768 (of the third portion) can latch the second portion of the AB signals and the WEB/WEBM signals, which can be passed through the third group of XOR gates 772, the transmission gate 774, and the NAND gate 778, and be latched in the latches 780-782.

In the SHIFT mode (e.g., SWT=0/1 and SSE=1), the portion 360A of the CNT DFT circuit 360 can receive the SIC signal, and pass it through the latch 710, the transmission gate 716, and further the NAND gate 718, to the latches 720-722. The portion 360B of the CNT DFT circuit 360 can receive the signal, latched in the latch 722, and pass it through the transmission gate 746 and further the NAND gate 748, to the latches 750-752. The portion 360C of the CNT DFT circuit 360 can receive the signal, latched in the latch 752, and pass it through the transmission gate 776 and further the NAND gate 778, to the latches 780-782. The latch 782 can provide the SOC signal being latched therein.

Referring again to FIG. 5, the I/O redundancy circuit 580, configured to generate the HIT2 signal, can include a local redundancy decoder 582, a NOR gate 584, and an inverter 586. The local redundancy decoder 582 (of each I/O column circuit 132) can receive a respective logic combination of thermal codes, which can be provided by a thermal coder. In some embodiments, the I/O redundancy circuit 580 may be formed as a part of the I/O circuit 130, while the thermal coder can be formed as a part of the CNT circuit 120 (e.g., 810 of FIG. 8). Upon receiving the thermal codes, the I/O redundancy circuit 580 can send a signal to be NOR'ed with the SWT signal, thereby generating the HIT2 signal through the inverter 586. Referring then to FIG. 8, the thermal coder 810 can receive repair address signals (e.g., Repair_Address <0:7>), which can indicate which of the memory columns has been detected as abnormal or malfunctional, and generate thermal codes (e.g., THMCA<1:3>, THMCA<1:7>, THMCA<1:5>). The thermal codes can then be processed by the I/O redundancy circuit 580 for generating the HIT2 signal. In the non-limiting example of FIG. 8, the I/O redundancy circuit 580 can include p-type transistors 822, 824, 826, 836, and 838, n-type transistors 828, 830, 832, 834, and 840, inverters 842, 844, and 848, and a NOR gate 846, as connected to one another.

FIG. 9 and FIG. 10 illustrate example circuit diagrams of an input level shifter 900 and an output level shifter 1000, respectively, in accordance with some embodiments. For example, each of the above-described input level shifters (e.g., 514-516, 564, 724-726, 754-756, 784-786) may be implemented as the input level shifter 900 configured to shift a signal from the VDD domain to the VDDM domain, as shown in FIG. 9; and each of the above-described output level shifters (e.g., 552, 566) may be implemented as the output level shifter 1000 configured to shift a signal from the VDDM domain to the VDD domain, as shown in FIG. 10. However, it should be understood that the input/output level shifters, included in the memory circuit 100, can be implemented as any of various other suitable circuit diagrams while remaining within the scope of the present disclosure.

The input level shifter 900, in FIG. 9, can include p-type transistors 902, 904, 908, and 910, n-type transistors 906 and 912, and an inverter 914. In some embodiments, the p-type transistors 902-904 and 908-910 and the n-type transistors 906 and 912 may operate in the VDDM domain, while the inverter 914 may operate in the VDD domain. The input level shifter 900 can receive an input signal (in the VDD domain), which is inputted to the inverter 914 and gate terminals of the transistors 904 and 906, and the input level shifter 900 can provide an output signal (in the VDDM domain), which is provided at a gate terminal of the transistor 902 and common source/drain terminals of the transistors 910 and 912.

The output level shifter 1000, in FIG. 10, can include p-type transistors 1002, 1004, 1008, and 1010, n-type transistors 1006 and 1012, and an inverter 1014. In some embodiments, the p-type transistors 1002-1004 and 1008-1010 and the n-type transistors 1006 and 1012 may operate in the VDDM domain, while the inverter 1014 may operate in the VDD domain. The output level shifter 1000 can receive an input signal (in the VDDM domain), which is inputted to the inverter 1014 and gate terminals of the transistors 1004 and 1006, and the output level shifter 1000 can provide an output signal (in the VDD domain), which is provided at a gate terminal of the transistor 1002 and common source/drain terminals of the transistors 1010 and 1012.

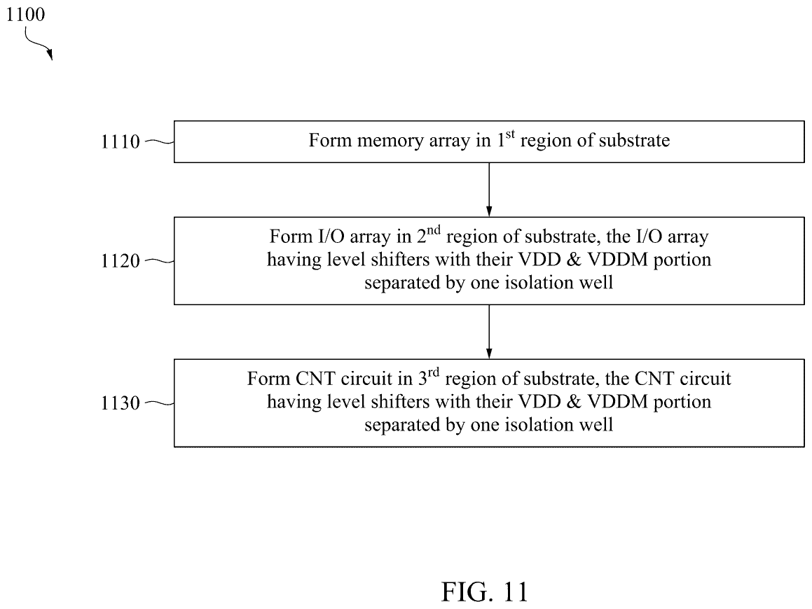

FIG. 11 illustrates a flow chart of an example method 1100 for forming a memory circuit, in accordance with some embodiments. The following discussion of the method 1100 may sometimes be referred to the above-described figures (e.g., FIGS. 3-4). It is noted that the method 1100 is merely an example and is not intended to limit the present disclosure. Accordingly, it is understood that additional operations may be provided before, during, and after the method 1100 of FIG. 11, and that some other operations may only be briefly described herein.

The method 1100 starts with operation 1110 of forming, in a first region of a substrate, a memory array including a plurality of memory cells. The substrate includes a semiconductor material substrate, for example, silicon. Alternatively, the substrate may include other elementary semiconductor material such as, for example, germanium. The substrate may also include a compound semiconductor such as silicon carbide, gallium arsenic, indium arsenide, and indium phosphide. The substrate may include an alloy semiconductor such as silicon germanium, silicon germanium carbide, gallium arsenic phosphide, and gallium indium phosphide. In one embodiment, the substrate includes an epitaxial layer. For example, the substrate may have an epitaxial layer overlying a bulk semiconductor. Furthermore, the substrate may include a semiconductor-on-insulator (SOI) structure. For example, the substrate may include a buried oxide (BOX) layer formed by a process such as separation by implanted oxygen (SIMOX) or other suitable technique, such as wafer bonding and grinding.

Along a major surface of the substrate, a plurality of transistors can be formed. In some embodiments, a first subgroup of the transistors, in the first region, can operatively form the memory cells of the array (e.g., 110 of FIG. 4), while other subgroups of the transistors operatively forming an I/O circuit (e.g., 130 of FIG. 4) and a CNT circuit (e.g., 120 of FIG. 3) can be physically formed in a second region and a third region of the substate, respectively, which will be discussed as follows. In some embodiments, the first to third regions, configured to form the memory array, the I/O circuit, and the CNT circuit, may be arranged based on the non-limiting block diagram of FIG. 1.

In some embodiments, the memory array may operation with a first voltage domain (e.g., VDDM), with each of the CNT circuit and the I/O circuit having respective portions that operate in the first voltage domain and a second voltage domain (e.g., VDD). Across the different voltage domains, the CNT circuit can include a number of level shifters that have their VDD portions and VDDM portions separated by only one isolation well, and the I/O circuit can include a number of level shifters that have their VDD portions and VDDM portions separated by only one isolation well. Advantageously, a total area of the memory array, the CNT circuit, and the I/O circuit, collectively forming a memory circuit, can be greatly recued.

The method 1100 proceeds to operation 1120 of forming, in a second region of the substrate, an input/output (I/O) array including a plurality of I/O column circuits, wherein the I/O array is operatively coupled to the memory array through a plurality of sense amplifiers. In some embodiments, the I/O column circuits can each include a respective portion of the W/R circuit 420 (e.g., at least one of the plurality of sense amplifiers), a respective portion of the I/O DFT circuit 430, a respective portion of the I/O feature circuit 470, and a respective portion of the I/O driver circuit 480, as shown in FIG. 4. Referring again to FIG. 4, the memory array 110, the W/R circuit 420, the I/O DFT circuit 430, and the VDDM portion of the level shifters 440 may be formed in a first sub-region of the second region, while the VDD portion of the level shifters 460, the I/O feature circuit 470, and the I/O driver circuit 480 may be formed in a second sub-region of the second region. Further, the VDDM portion of the level shifters 440 (e.g., an edge of the first sub-region of the second region) and the VDD portion of the level shifters 460 (e.g., an edge of the second sub-region of the second region) can be separated by only one isolation well 450.

The method 1100 proceeds to operation 1130 of forming, in a third region of the substrate, a control circuit. In some embodiments, the control circuit can include the WL driver 310, the CNT mission circuit 320, the CNT DFT circuit 360, and the other CNT circuits 370, as shown in FIG. 3. Referring again to FIG. 3, the WL driver 310, the CNT mission circuit 320, and the VDDM portion of the level shifters 330 may be formed in a first sub-region of the third region, while the VDD portion of the level shifters 350, the CNT DFT circuit 360, and the other CNT circuits 370 may be formed in a second sub-region of the third region. Further, the VDDM portion of the level shifters 340 (e.g., an edge of the first sub-region of the third region) and the VDD portion of the level shifters 350 (e.g., an edge of the second sub-region of the third region) can be separated by only one isolation well 340.

In one aspect of the present disclosure, a circuit is disclosed. The circuit includes a memory array including a plurality of memory cells disposed across a plurality of columns; and a plurality of input/output (I/O) circuits, each of the I/O circuits including a corresponding one of a plurality of sense amplifiers that is operatively coupled to a corresponding subset of the plurality of memory cells disposed in a corresponding one of the plurality of columns. Each of the I/O circuits includes a first input level shifter, a second input level shifter, and an output level shifter, each of the first input level shifter, the second input level shifter, and the output level shifter being coupled between a first voltage domain and a second voltage domain. The output level shifter has an input directly coupled to an output of a first multiplexer, the first multiplexer operating in the second voltage domain and configured to select one of a first signal present on a first input of the first multiplexer or a second signal present on a second input of the first multiplexer based on a first control signal.

In another aspect of the present disclosure, a circuit is disclosed. The circuit includes a first input/output (I/O) circuit including: a first sense amplifier configured to identify a data bit read out from at least one corresponding first memory cell; a first level shifter configured to convert a first data signal from a first voltage domain to a second voltage domain; a second level shifter configured to convert a second data signal from the first voltage domain to the second voltage domain; a third level shifter configured to convert a third data signal from the second voltage domain to the first voltage domain; and a first multiplexer operating in the second voltage domain, and configured to select, based on a first control signal, one of a logic combination of the first and second signals or the data bit as the third signal. The third level shifter is directly coupled to the first multiplexer.

In yet another aspect of the present disclosure, a method for forming a memory circuit is disclosed. The method includes forming, in a first region of a substrate, a memory array including a plurality of memory cells; and forming, in a second region of the substrate, a plurality of input/output (I/O) column circuits, the I/O column circuits operatively coupled to the memory array through a plurality of sense amplifiers. Each of the I/O column circuits comprises a first level shifter, a second level shifter, and a third level shifter. Each of the first to third level shifters includes a first portion operating with a first voltage domain and a second portion operating with a second voltage domain. The respective first portions of the first to third level shifters are formed in a first sub-region of within the second region, and the respective second portions of the first to third level shifters are formed in a second sub-region of the second region. The first sub-region and the second sub-region of the second region are separated from each other through only one isolation well.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
a memory array including a plurality of memory cells disposed across a plurality of columns; and
a plurality of input/output (I/O) circuits, each of the I/O circuits including a corresponding one of a plurality of sense amplifiers that is operatively coupled to a corresponding subset of the plurality of memory cells disposed in a corresponding one of the plurality of columns;
wherein each of the I/O circuits includes a first input level shifter, a second input level shifter, and an output level shifter, each of the first input level shifter, the second input level shifter, and the output level shifter being coupled between a first voltage domain and a second voltage domain; and
wherein the output level shifter has an input directly coupled to an output of a first multiplexer, the first multiplexer operating in the second voltage domain and configured to select one of a first signal present on a first input of the first multiplexer or a second signal present on a second input of the first multiplexer based on a first control signal.

2. The circuit of claim 1, wherein the first signal represents a data signal captured in a Design-for-Testing (DFT) mode, and the second signal represents a data bit read out through the corresponding sense amplifier in a NORMAL mode.

3. The circuit of claim 1, wherein the first signal is propagated through the first input level shifter, selected by a second multiplexer operating in the second voltage domain, and propagated through at least an XOR gate, a NAND gate, and a latch circuit.

4. The circuit of claim 3, wherein the XOR gate and the NAND gate each operate in the second voltage domain.

5. The circuit of claim 3, wherein the second multiplexer is configured to select one of the first signal or a third signal based on a second control signal.

6. The circuit of claim 5, wherein the NAND gate has a first input configured to receive the first signal or the third signal selected by the second multiplexer, and a second input configured to receive a logic combination of the first control signal and the second control signal.

7. The circuit of claim 6, wherein the third signal is provided by another one of the plurality of columns.

8. The circuit of claim 7, wherein the third signal is configured to be provided to yet another one of the plurality of columns.

9. The circuit of claim 1, wherein the output level shifter has an output directly coupled to a transmission gate operating in the first voltage domain, without a buffer coupled therebetween.

10. The circuit of claim 1, wherein a first one and a second one of the I/O circuits, physically disposed along edges of the memory array, respectively, each include an additional level shifter.

11. A circuit, comprising:
a first input/output (I/O) circuit including:
a first sense amplifier configured to identify a data bit read out from at least one corresponding first memory cell;
a first level shifter configured to convert a first data signal from a first voltage domain to a second voltage domain;
a second level shifter configured to convert a second data signal from the first voltage domain to the second voltage domain;
a third level shifter configured to convert a third data signal from the second voltage domain to the first voltage domain; and
a first multiplexer operating in the second voltage domain, and configured to select, based on a first control signal, one of a logic combination of the first and second signals or the data bit as the third signal;
wherein the third level shifter is directly coupled to the first multiplexer.

12. The circuit of claim 11, wherein the first multiplexer selects the logic combination of the first and second signals as the third signal, when the circuit is configured in a Design-for-Testing (DFT) mode through at least the first control signal being provided at a first logic state.

13. The circuit of claim 11, wherein the first multiplexer selects the data bit identified by the first sense amplifier as the third signal, when the circuit is configured in a NORMAL mode through at least the first control signal being provided at a second logic state.

14. The circuit of claim 11, wherein the first I/O circuit comprises:
a second multiplexer operating in the second voltage domain;
a first logic gate operating in the second voltage domain;
a second logic gate operating in the second voltage domain;
a first latch circuit operating in the second voltage domain; and
a second latch circuit operating in the second voltage domain.

15. The circuit of claim 14, wherein the second multiplexer is directly coupled to the first level shifter and configured to select, based on a second control signal, one of the first data signal or a fourth signal provided by a second I/O circuit.

16. The circuit of claim 15, wherein the first logic gate is configured to perform an XOR operation on the first data signal and the second data signal.

17. The circuit of claim 16, wherein the second logic gate is configured to perform a NAND operation on an output of the first logic gate and a logic combination of the first and second control signals.

18. The circuit of claim 15, wherein the second I/O circuit includes a second sense amplifier configured to identify a data bit read out from at least one corresponding second memory cell, and is physically located next to the first I/O circuit.

19. A method, comprising:
forming, in a first region of a substrate, a memory array including a plurality of memory cells; and
forming, in a second region of the substrate, a plurality of input/output (I/O) column circuits, the I/O column circuits operatively coupled to the memory array through a plurality of sense amplifiers;
wherein each of the I/O column circuits comprises a first level shifter, a second level shifter, and a third level shifter;
wherein each of the first to third level shifters includes a first portion operating with a first voltage domain and a second portion operating with a second voltage domain;
wherein the respective first portions of the first to third level shifters are formed in a first sub-region of within the second region, and the respective second portions of the first to third level shifters are formed in a second sub-region of the second region; and
wherein the first sub-region and the second sub-region of the second region are separated from each other through only one isolation well.

20. The method of claim 19, further comprising:
forming, in a third region of the substrate, a control circuit operatively coupled to the memory array;
wherein the control circuit comprises a plurality of fourth level shifters;
wherein each of the fourth level shifters includes a first portion operating with the first voltage domain and a second portion operating with the second voltage domain; and
wherein the respective first portions of the fourth level shifters are formed in a first sub-region of within the third region, and the respective second portions of the fourth level shifters are formed in a second sub-region of the third region; and
wherein the first sub-region and the second sub-region of the third region are separated from each other through only one isolation well.
